(19) United States
(12) Patent Application Publication
(10) Pub. No.: US 2025/0077748 A1
(43) Pub. Date: Mar. 6, 2025

(54) METHOD OF INTELLIGENT PREDICTION OF COAL STRESS AND DIFFERENT DIAMETERS PRESSURE RELIEF BASED ON OPTIMIZATION NEURAL NETWORK

(71) Applicant: SHANDONG UNIVERSITY OF SCIENCE AND TECHNOLOGY, Qingdao (CN)

(72) Inventors: Hengjie Luan, Qingdao (CN); Jiankang Liu, Qingdao (CN); Jianrong Liu, Qingdao (CN); Yujing Jiang, Qingdao (CN); Qinghua Xiao, Qingdao (CN); Zhenqi Song, Qingdao (CN); Yantai Guan, Qingdao (CN); Changsheng Wang, Qingdao (CN); Dong Wang, Qingdao (CN)

(73) Assignee: SHANDONG UNIVERSITY OF SCIENCE AND TECHNOLOGY, Qingdao (CN)

(21) Appl. No.: 18/814,750

(22) Filed: Aug. 26, 2024

Related U.S. Application Data
(63) Continuation-in-part of application No. 18/510,177, filed on Nov. 15, 2023.

(30) Foreign Application Priority Data
Sep. 1, 2023 (CN) 2023111218926

(51) Int. Cl. G06F 30/28; G01V 20/00

(52) U.S. Cl. CPC G06F 30/28; G01V 20/00

(57) ABSTRACT

A method of intelligent prediction of coal stress and different diameters pressure relief based on optimization neural network collects the drilling parameters while drilling the pressure-relief boreholes at one working face and to obtain the stress values using the accompanying boreholes of the pressure-relief boreholes to construct the prediction model; in this way, the prediction model is applied to predict the value of mining stress when drilling pressure-relief borehole in other working faces; according to the prediction results, the distribution law of mining stress is analyzed, and then the reaming position, length of reaming section and hole diameter of the pressure relief borehole are determined; the present invention monitors the pressure-relief borehole construction process of accompanying borehole parameters at the same time, monitoring the adjacent accompanying borehole corresponding to the depth of the drilling borehole coal stress value.

### CROSS-REFERENCE TO RELATED APPLICATIONS

This application is a continuation-in-part application of US 18/510,177 filed on 15 Nov. 2023 that claims priority to Chinese Patent Application Ser. No. CN2023111218926 filed on 1 Sep. 2023.

### TECHNICAL FIELD

The present invention belongs to the field of underground engineering safety, especially to the field of prevention and control of underground impact pressure in coal mines using an intelligent prediction model combining with-drill signal detection technology and intelligent prediction technology. Specifically, it relates to a method of intelligent prediction of coal stress and different diameters pressure relief based on optimization neural network.

### BACKGROUND ART

Coal stress with the advancement of the working face is dynamic development and change, underground impact pressure and other dynamic disasters occur is the result of mining stress development and accumulation. At present, the drill hole pressure-relief borehole is one of the more commonly used methods to reduce the risk of coal impact, generally using equal diameter pressure-relief borehole. However, if the diameter of the pressure-relief borehole is too small, the expected pressure-relief effect cannot be achieved, and if the diameter of the hole is too large, it will cause damage to the surrounding rock and affect the stability of the surrounding rock. In order to realize accurate pressure relief, different diameters pressure relief technology has been developed at this stage. The different diameters pressure relief refers to the pressure relief from the surface of the surrounding rock to the depth of the surrounding rock drilling, the pressure relief drilling along the depth of the hole in the high stress areas need to be reamed to artificially change the distribution of stress in the surrounding rock. Compared with the traditional equal diameter pressure relief, different diameters pressure relief is more effective and can better protect the integrity of the surrounding rock. However, in order to achieve better decompression effect, the location of reaming needs to be decided according to the distribution of coal stress. The measure taken by the existing technology is to select a few representative locations within a certain distance to drill stress monitoring holes to monitor the stress at different depths. According to the monitoring results to determine the reaming parameters, so that all the pressure-relief borehole within the range of the fixed reaming parameters in accordance with the construction, which is essentially a rough method of reaming pressure relief. Therefore, how to measure the distribution of coal stress conveniently and quickly has become a bottleneck problem restricting the development of different diameters pressure relief technology.

The traditional drilling pressure relief method uses the amount of coal dust discharged from the drilling construction to indirectly reflect the coal stress, and there is an error in the numerical conversion process; the discharged coal dust needs to be weighed manually, which can not realize the rapid measurement of coal stress; the weighing of the coal dust needs to pause the drilling construction, which leads to the discontinuous monitoring of the parameters of the drilling process, and the frequent starting of the drilling rig may easily lead to the monitoring of the parameters of the drilling process, which are mostly anomalous; the data volume of the drilling parameters is huge, and the processing efficiency of the traditional method is low. Due to the above reasons, the traditional method of pressure relieving in drilling holes lacks precise guidance measures, and it is impossible to achieve precise and efficient pressure relieving effect.

The drilling parameters are characterized by a large number and variety of characteristics, and have a complex nonlinear relationship with coal stress, and the traditional linear and nonlinear methods are unable to establish a correlation model between the two. Artificial neural network is a mathematical model that applies a structure similar to the synaptic connections of the brain for information processing, and it is a kind of arithmetic model, which has been widely used in pattern recognition, signal processing, knowledge engineering, expert system, optimization combination, robot control and so on. However, artificial neural network technology is prone to overfitting problems and is difficult to ensure prediction accuracy. Genetic algorithm is an optimization algorithm that simulates natural selection and genetic mechanism to search for the optimal solution by simulating the evolutionary process, which can be used to automatically adjust the network structure and weight parameters to improve the prediction performance of neural networks. However, the use of neural networks and optimized neural network prediction model to solve the technical difficulties of intelligent prediction of rock mechanical parameters with drilling in coal mine underground has not been realized yet, and the key technologies that plague the realization of this technology are: Firstly, hardware testing equipment is needed to detect the drilling signals. Secondly, the collected drilling signals should be processed by computer system to establish the corresponding intelligent prediction model. Thirdly, the key premise of the above hardware detection equipment and the establishment of intelligent prediction model is also to coordinate the drilling construction of underground coal mine peripheral rock drilling holes, the collection of drilling parameters, and the reasonable allocation of time and space for the collection of drilling parameters used for the training of computational modeling and prediction design.

For this reason, it is necessary to study an operationally accurate pressure relief method that combines drill-following signal detection and intelligent prediction techniques.

### SUMMARY OF THE INVENTION

In order to conveniently and quickly measure the distribution of coal stress and realize accurate pressure relief for mines with impact tendency, the present invention provides an intelligent prediction of coal stress and a different diameters pressure relief method based on an optimization neural network.

The technical solutions adopted in the present invention to achieve the above objectives are:

A method for intelligent prediction of coal stress and different diameters pressure relief based on an optimization neural network, comprising a computer readable medium operable on a computer with memory for the method of intelligent prediction of coal stress and different diameters pressure relief based on optimization neural network, and comprising program instructions for executing the following steps:

### S1: Training Set Data Acquisition

S1.1: Select a sampling working face in the direction of advancement of the mining working face, design pressure-relief boreholes at the sampling working face according to the degree of risk of underground impact pressure, and design at least one accompanying borehole near each pressure-relief borehole for stress monitoring;

### S1.2: Drilling Construction and Data Acquisition

S1.2.1: First, the accompanying borehole is drilled, and the method of drilling the accompanying borehole is divided into the following two construction scenarios:

In the first case, when the coal has a Proctor's coefficient value <3.0, an accompanying borehole is drilled parallel to it near each pressure-relief borehole. The accompanying borehole and the pressure-relief borehole are at the same level and at the same depth, and a plurality of hole stress gauges are set up at equal intervals along the depth in the accompanying borehole;

In the second case, when the coal has a Proctor's coefficient value <3.0, a number of accompanying boreholes of equal increasing depth are drilled at equal intervals around the week of the pressure-relief borehole. The depth of the deepest accompanying borehole is equal to the depth of the pressure-relief borehole, and a borehole stress gauge is placed at the bottom of each accompanying borehole;

S1.2.2: After the accompanying borehole is drilled, drilling of the pressure-relief borehole is started. Each time the pressure-relief borehole is drilled to a position at the same depth as the accompanying borehole's drilled stress gauge, the driller's accompanying drilling parameters are collected as a, and the stress value of that stress gauge is also collected as b;

### S2: Build Prediction Model

### S2.1: Sample Dataset Organization

The collation of all the pressure-relief borehole drilling collected during the drilling of the pressure-relief borehole a and the stress values b from the accompanying borehole stress gauges form the training set;

### S2.2: Establishment of Neural Network Prediction Model

Adopting the coefficient of determination R2 as the evaluation index of model prediction accuracy, setting different numbers of training samples, hidden layers, hidden layer nodes, and different combinations of random drill parameters as independent variables, and the model prediction accuracy as the dependent variable, the comparison experiments of the corresponding artificial neural network models are established. The effects of the number of training samples, hidden layers, hidden layer nodes and different combinations of input feature parameters on the model prediction accuracy are examined. The optimal number of training samples, hidden layers, hidden layer nodes, and the optimal combination of feature parameters are preferred based on the impact results. The neural network prediction model is established based on the optimal number of training samples, implicit layers, implicit layer nodes, and the optimal combination of feature parameters that are preferred;

### S2.3: Establishment of Optimized Neural Network Model

Genetic algorithm and particle swarm algorithm were used to optimize the neural network prediction model established in S2.2, respectively;

S2.4: The best neural network prediction model is preferred by comparing the coefficients of determination of a total of three neural network prediction models obtained in steps S2.2 and S2.3;

### S3: Intelligent Prediction of Coal Stress and Different Diameters Pressure Relief

### S3.1: Intelligent Prediction of Coal Stresses

The working face adjacent to the sampling working face was selected as the prediction working face, and the parameters of the accompanying drilling were collected at the same time when the pressure-relief borehole construction was carried out at the prediction working face. The optimal neural network prediction model that has been constructed in step S2 is used to predict coal stress in real time;

### S3.2: Determine the Different Diameters Pressure Relief Scheme According to the Coal Stress Distribution Law

Drilling pressure relief is a conventional measure to prevent and control underground impact pressure, but there are many problems with the conventional equal-diameter pressure relief technology: 1) Conventional equal-diameter pressure relief technology adopts a single borehole diameter for pressure relief, and the degree of pressure relief can only rely on adjusting the density of pressure relief holes (the density of pressure holes is the number of pressure relief holes per unit area), so the effect of pressure relief can't be accurately controlled. When the drilling density is small, the pressure relief effect is not obvious, and the safety of anti-punching is affected; When the drilling density is large, the construction speed is slow, and the integrity of the surrounding rock structure is affected to some extent; 2) The working face mining is a dynamic process, and the coal stress is dynamically changing with the advancement of the working face. At present, the real-time dynamic perception of coal stress has been a problem in the industry. Most of the monitoring of coal stress relies on pre-installed stress sensors, with limited monitoring range and lagging monitoring time, which can't be obtained in time and feedback regulation.

The invention starts from solving the practical problem that it is difficult to realize accurate pressure relief by conventional equal-diameter pressure relief, and based on the monitoring of rotary speed, feed pressure, motor torque and other accompanying drilling parameters during the construction of pressure relief drilling holes, it adopts artificial intelligence technology to intelligently predict the change of the coal stress in the drilling area. According to the pressure relief theory and diameter change technology, the pressure relief parameters such as drilling diameter and drilling speed are dynamically adjusted and optimized: Based on the predicted value of coal stress, analyze the stress distribution law of the coal and distinguish the high stress area and low stress area. Determine the reaming position and section length of the pressure relief drilling according to the distribution of the high stress area, and determine the reaming diameter according to the stress size of the high stress area. When the pressure relief drilling construction reaches the reaming position, the reaming construction is carried out according to the determined reaming section length and hole size.

Based on the predicted value of coal stress, analyze the coal stress distribution law and distinguish the high stress area and low stress area. Determine the reaming position and the length of the hole diameter section of the pressure relief drill hole according to the distribution of the high stress area. Determine the hole diameter of the reaming hole according to the stress size of the high stress zone. When the pressure-relief borehole drilling reaches the reaming position, the reaming construction is carried out according to the determined reaming section length and aperture size, and the purpose of accurate pressure relief is finally realized;

The technology of the invention has the following advantages in comparison with the conventional technology: 1) The effect of pressure relief is precise and controllable, the range of pressure relief hole diameter is optimized from single hole diameter to continuous variable hole diameter, and the number of pressure relief holes can be reduced by 50%; 2) The collection and analysis of drilling parameters can be realized, and the dynamic control of pressure relief in the drilling holes in the high-risk area of impact can be realized. The construction efficiency of pressure relief holes is increased from 25 m/day to 40 m/day, and the drilling construction is changed from the original three persons working in close proximity to one person working remotely from a distance, which shortens the exposure time of personnel in dangerous areas.

Therefore, the adoption of the above technology can not only improve the construction efficiency, but also ensure the safe mining of impact high-risk coal resources, and ultimately achieve the purpose of accurate pressure relief.

### S3.3: Predictive Modeling Corrections

The best neural network prediction model is corrected at regular intervals when pressure relief drilling is performed at the prediction face. The corrected neural network prediction model is utilized to predict the value of stress at the time of coal stress.

Further, the specific process of step S3.3 predictive model revision is:

When pressure-relief boreholes are drilled at the prediction working face, a number of pressure-relief boreholes are selected at intervals to be drilled with stress-monitoring accompanying boreholes as verification accompanying boreholes. Construct the accompanying boreholes according to the method of step S1.2 and collect the stress values and the parameters of the pressure-relief boreholes at the corresponding locations, forming a validation dataset, and based on this validation dataset, verify the error of the optimal neural network prediction model of step S2.4. If the error exceeds the set range (the error value can be set according to the actual situation, such as setting the coefficient of determination greater than 0.8), the validation dataset will be added to the training sample set in step S1. The model is then corrected, and the corrected neural network prediction model is used to predict the value of coal stress at the time of mining, and if the error is within the set range, the model does not need to be corrected.

Further, the drilling-following parameter a described in step S1.2.2 includes drilling parameters and vibration parameters. Said drilling parameters include rotational speed, feed pressure, motor torque, current voltage and real-time power of the motor. Said vibration parameters include mean value, standard deviation, mean square deviation and center of gravity frequency.

The Proctor's coefficient value f described in the present invention is also known as the rock solidity coefficient, fastening coefficient, and is calculated by the formula f=R/10, where R is the uniaxial compressive strength of the rock in MPa. The critical value of the Proctor's coefficient value for distinguishing between the softness and hardness of the coal quality can be selected according to the specific conditions of the site.

The coefficient of determination described in the present invention is a commonly used evaluation index for evaluating the performance of neural network models, and its calculation method is public knowledge and common sense, so it will not be described in detail here.

The following describes the positive effects of the present invention in relation to the existing technology.

For impact-prone mines, drilling pressure relief boreholes to the working face is a common anti-impact measure. The existing technology is generally based on the working conditions and experience on-site drilling of equal-diameter decompression holes to decompress, which is equivalent to taking the surrounding rock stress as a constant value. In fact, with the increase of depth, the stress difference between deep and shallow perimeter rock is large, and the use of equal-diameter pressure relief borehole will easily lead to too small or too large pressure-relief borehole. If the diameter of the pressure-relief borehole is too small, the expected pressure-relief effect cannot be achieved, and if the diameter of the hole is too large, it will cause damage to the surrounding rock and affect the stability of the surrounding rock. In the present invention, when drilling pressure-relief boreholes, the drilling parameters are collected when drilling pressure-relief boreholes in one working face, and the accompanying borehole of the pressure-relief boreholes is used to obtain the stress value to construct a prediction model. In this way, the constructed prediction model can be used to predict the stress value of each pressure-relief borehole in real time, quickly and accurately when drilling pressure-relief boreholes in other working faces. At the same time, an accompanying borehole is set at a certain distance to correct the prediction model and improve the accuracy of coal stress prediction, so as to predict in advance the location of the pressure relief boreholes to be reamed and the size of the reamed holes to realize accurate pressure relief.

### BRIEF DESCRIPTION OF THE FIGURES

In order to more clearly illustrate the technical solutions in the embodiments or prior art of the present invention, the accompanying drawings to be used in the description of the embodiments or prior art will be briefly described below. Obviously, the accompanying drawings in the following description are only some of the embodiments of the present invention, and other accompanying drawings may be obtained based on these drawings by a person of ordinary skill in the art without creative labor.

FIG. 1 is a diagram of a drilling arrangement scheme for a sampling working face in Example 1 of the present invention;

FIG. 2 is a diagram of a different diameters pressure relief prediction scheme implemented in a working face adjacent to the sampling working face of Example 1;

FIG. 3 is a diagram of the drilling arrangement scheme of the sampling working face of Example 2 of the present invention;

FIG. 4 is a three-dimensional view of the arrangement scheme of the pressure-relief borehole and the stress-monitoring accompanying borehole of Example 2;

FIG. 5 is a side view of the arrangement scheme of the pressure-relief borehole and the stress-monitoring accompanying borehole of Example 2;

FIG. 6 is a top view of the arrangement scheme of the pressure-relief borehole and the stress-monitoring accompanying borehole of Example 2;

FIG. 7 is a diagram of a different diameters precise pressure-relief relief prediction scheme implemented at a working face adjacent to the sampling working face of Example 2 (verification accompanying boreholes are omitted from the diagram).

In the picture:

1—pressure-relief borehole, 2—accompanying borehole, 3—stressometer, 4—different diameters pressure relief borehole, 5—verification of accompanying borehole.

2₁, 2₂, 2₃ . . . 2ᵢ represents the first accompanying borehole, the second accompanying borehole, the third accompanying borehole . . . the ith accompanying borehole, in that order.

### DETAILED EMBODIMENTS

The construction process of the embodiments of the present invention is described in detail below in conjunction with the accompanying drawings, so that the advantages and features of the present invention can be more easily understood by those skilled in the art. Thus, the scope of protection of the present invention is more clearly defined.

The technical solution of the present invention is described in detail below using two mines with underground impact pressure risk as examples.

### Example 1 is an example of a mine with a hard coal rock with a Proctor's coefficient value ≥3.0

### S1: Training Set Data Acquisition

### S1.1: Drill Design

As shown in FIG. 1, a working face is used as the sampling working face, and the locations of pressure-relief boreholes (including the hole spacing and row spacing of the pressure-relief borehole 1), as well as the hole diameters and depths of the holes are designed according to the degree of risk of underground impact pressure at the site, in the coal gangs of the head entry in the direction of the mining working face advancement. At the same time, an accompanying borehole 2 is designed in the vicinity of each pressure-relief borehole 1, for example, one meter away from the pressure-relief borehole 1. The height of the accompanying borehole 2 and the corresponding pressure-relief borehole 1 from the bottom plate are the same and parallel, and the depths of the holes in both are the same;

### S1.2: Drilling Construction and Data Acquisition

Before drilling the pressure-relief borehole 1, the accompanying borehole 2 is first drilled, in which stress gauges 3 are set at one meter intervals along the depth of the borehole. then the pressure-relief borehole 1 is constructed, and the pressure-relief borehole 1 is an equal-diameter drilled hole. During the drilling of the pressure-relief borehole 1, the accompanying drilling parameters a are collected at intervals of one meter, including drilling parameters (rotational speed, feed pressure, motor torque, current and voltage, and real-time power of the motor, etc.) and vibration parameters (mean, standard deviation, mean square deviation, and frequency of the center of gravity, etc.). Simultaneous acquisition of stress values b from the stress gauges in the accompanying borehole 2 corresponding to this pressure-relief borehole 1.

### S2: Build Prediction Model

### S2.1: Sample Dataset Organization

The collation of all the pressure-relief borehole 1 drilling with the drilling parameters a and the stress values b in the accompanying borehole 2 were collected to form the training set.

### S2.2: Establishment of Neural Network Prediction Model

Adoption of the coefficient of determination R2 as an evaluation index of model prediction accuracy.

Different numbers of training samples, hidden layers, hidden layer nodes and different combinations of input feature parameters are set as independent variables. The model prediction accuracy, which is also known as the coefficient of determination R2, is used as the dependent variable to set up a comparison experiment of the corresponding artificial neural network model. The effects of the number of training samples, hidden layers, hidden layer nodes and different combinations of input feature parameters on the model recognition accuracy are examined to obtain the best neural network model;

The described combinations of different input characteristic parameters can be a full combination of the drill-following parameters. For example, the rotary speed, feed pressure, motor torque, current and voltage, motor real-time power, average value, standard deviation, mean square deviation, center of gravity frequency and other 9 with the drilling parameters of the full combination of the way a total of 511 combination samples. When there are more drilling parameters, the number of combination samples is very large, and the model calculation is large, wasting computational resources. At this time, the first use of principal component analysis to reduce the dimensionality of the drilling parameters, such as down to 5 dimensions, that is, 5 types of characteristic parameters. The 5 types of feature parameters as independent variables into the neural network model for training. After training, the best neural network prediction model corresponding to the combination of samples in the feature parameters will be the subsequent prediction of the need to collect with the drill parameters.

### S2.3: Establishment of Optimized Neural Network Model

The algorithms such as genetic algorithm and particle swarm algorithm are used to optimize the best neural network model established in step 2.2 respectively. The best neural network model optimized by genetic algorithm and the best neural network model optimized by particle swarm algorithm are obtained respectively;

S2.4: The best neural network prediction model is preferred by comparing the best neural network model established in step 2.2 and the coefficients of determination of the two best neural network models obtained by optimization of the two algorithms in step S2.3;

### S3: Intelligent Prediction of Coal Stress and Different Diameters Pressure Relief

### S3.1: Intelligent Prediction of Coal Stresses

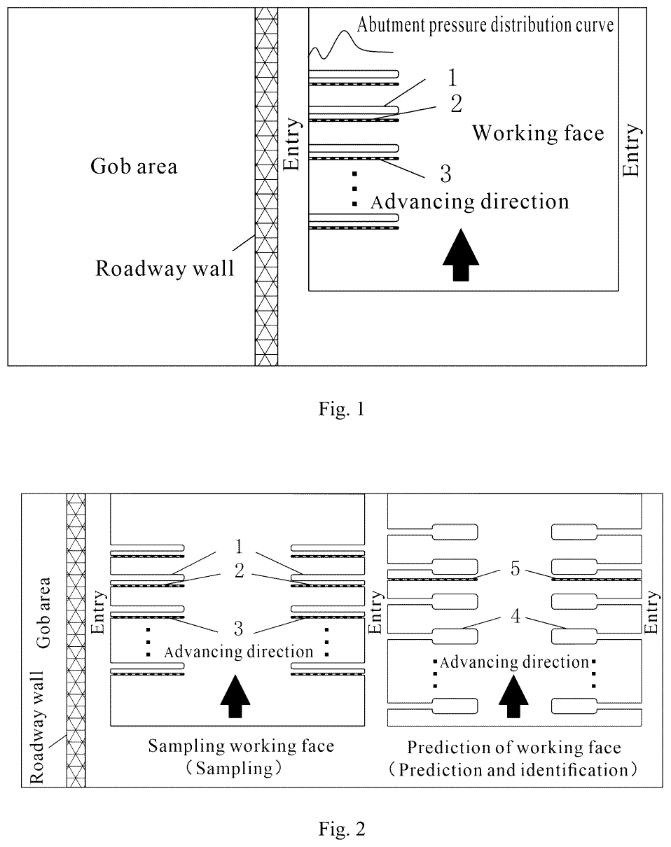

As shown in FIG. 2, the adjacent working face of the sampling working face is selected as the prediction working face. The prediction working face was drilled, and because the surrounding rock surface and the shallow coal stress were small, the construction was started by drilling equal-diameter holes (equal-diameter section of different diameters pressure-relief borehole 4 in FIG. 2). During the drilling process, the following drilling parameters are collected as input parameters, and the optimal neural network prediction model constructed in step 2 is used to predict the coal stress in real time;

### S3.2: Determine the Different Diameters Pressure Relief Scheme According to the Coal Stress Distribution Law

According to the coal stress prediction value, analyze the coal stress distribution law, distinguish the high stress area and low stress area, and determine the expansion position of the different diameters pressure relief borehole 4 (see the expansion section of the different diameters pressure relief borehole 4 in FIG. 2). Determine the expansion position and length of the expansion section of the different diameters pressure relief borehole 4 according to the distribution range of the high stress zone. According to the stress size of the high stress area to determine the hole expansion construction of different diameters pressure relief, and ultimately realize the purpose of accurate pressure relief.

### S3.3: Predictive Modeling Corrections

When pressure-relief boreholes are drilled in the predicted working face, a number of pressure-relief boreholes are drilled at intervals (which can be adjusted according to the actual situation in the site) and the stress monitoring accompanying boreholes are called validation accompanying boreholes 5. The validation accompanying boreholes 5 are equipped with the stress gauges 3 in accordance with the manner of step S1.2, and when the pressure-relief boreholes corresponding to the validation accompanying boreholes 5 are drilled. Simultaneously, the drilling parameters and the stress values of the stress gauges in the verification accompanying borehole 5 are collected to form a verification data set. Based on this validation dataset, the optimal neural network prediction model of step S2.4 is validated for errors.

If the error exceeds a certain range (the error value can be set by itself according to the actual situation, such as setting the coefficient of determination to be greater than 0.8), the validation dataset will be added to the training sample set of step S1, and thus the optimal neural network prediction model will be corrected. If the error is within a certain range, the optimal neural network prediction model does not need to be corrected.

Example 2 is an example of a softer coal mine with a Proctor's coefficient value <3.0

Example 2 differs from Example 1 mainly in: first, the design and construction of the accompanying borehole is different at step S1 training set data collection; second, the drilling method for verifying the accompanying borehole 5 is different at step S3.3 prediction model correction. Specifically embodied in.

### S1: Training Set Data Acquisition

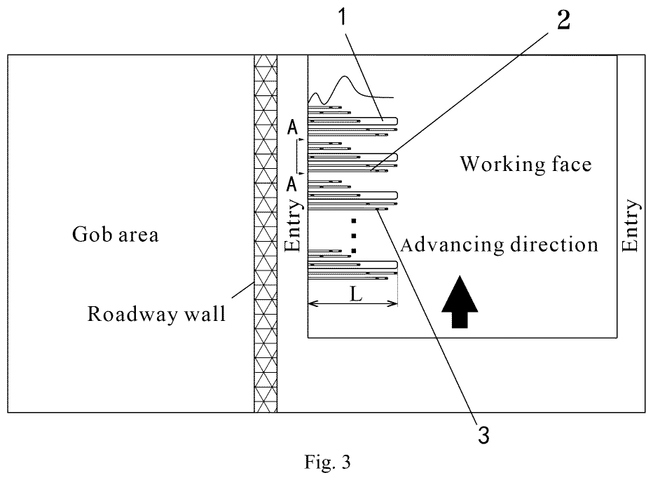

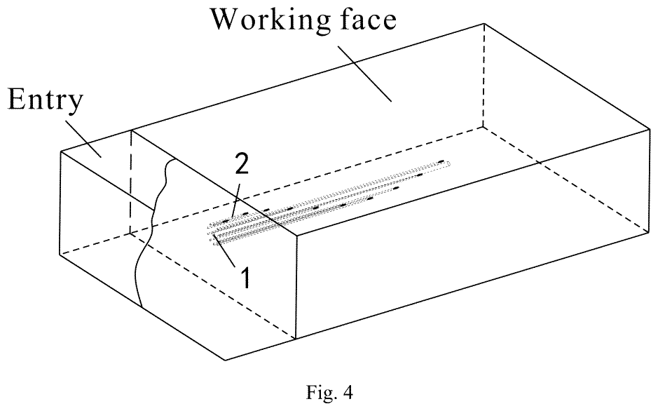

S1.1: In conjunction with FIGS. 3-6, the boreholes are designed and constructed with a circle of accompanying boreholes 2 for stress monitoring around each pressure-relief borehole 1. For example, a plurality of accompanying boreholes 2 are drilled at equal spacing on a circle centered on the pressure-relief borehole 1 with a radius of 1 m. The depths of the plurality of accompanying boreholes 2 are sequentially and equally increased, with the deepest of the accompanying boreholes 2 being equal in depth to the depth of the pressure-relief borehole 1. Wherein the number and depth of the accompanying boreholes are determined as follows:
1) Determination of the number of accompanying boreholes 2

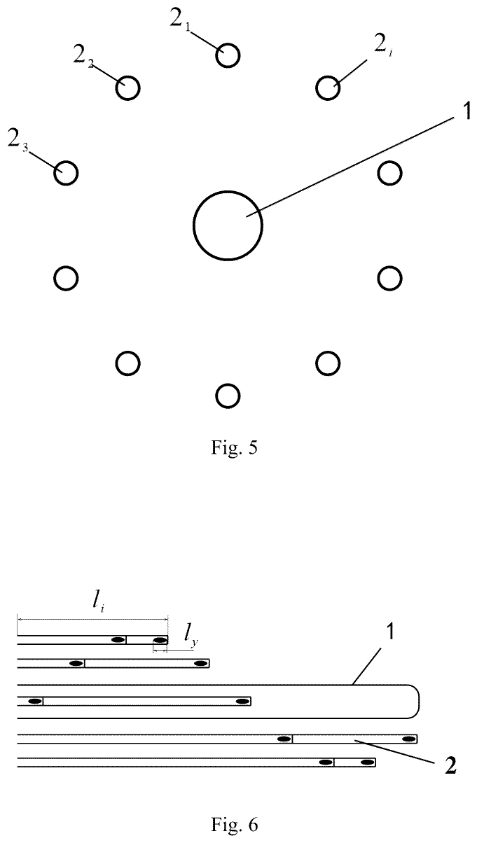

As shown in FIG. 5, if the depth of the pressure-relief borehole 1 is an integer L meters (when L is not an integer, it is rounded to the nearest integer), and if it is pre-designed to collect the accompanying drilling parameters for every one meter of drilling, the number of accompanying boreholes 2 is L, with the aim of realizing the collection of one stress value for every meter of drilling. The L accompanying boreholes 2 in FIG. 5 are numbered counterclockwise as the first accompanying borehole 21, the second accompanying borehole 22, the third accompanying borehole 2₃ . . . the i-th accompanying borehole 2ᵢ, where i is 1,2,3 . . . L. For example, when the depth of the pressure-relief borehole 1 is 10 meters, the number of accompanying boreholes 2 is 10, when the depth of the pressure-relief borehole 1 is 9.4 meters, the number of accompanying boreholes 2 is 9, and when the depth of the pressure-relief borehole 1 is 10.5 meters, the number of accompanying boreholes 2 is 11.
2) Determination of depth Lᵢ of accompanying borehole 2

As shown in FIG. 6, if the length of the adopted stress gauge is L_{y} meters, the depth (in meters) of the first accompanying borehole 21, the second accompanying borehole 22, the third accompanying borehole 2₃ . . . the i-th accompanying borehole 2i is calculated as: L=i+L_{y}/2, where i is 1,2,3 . . . L. That is, the installation of the stress gauge 3 ensures that the center of the stress gauge 3 is located at a position where the depth of the corresponding accompanying borehole is subtracted from half the length of the stress gauge;

### S1.2: Borehole Construction

First, the first accompanying borehole 21, the second accompanying borehole 22, the third accompanying borehole 2₃ . . . the i-th accompanying borehole 2; is constructed according to the designed number of accompanying boreholes 2 and the depth of each accompanying borehole 2, and a stress gauge is installed at the bottom of each accompanying borehole 2. After the construction of the accompanying boreholes 2 is completed, the drilling of the pressure-relief borehole 1 is started, and when the pressure-relief borehole 1 is drilled to a depth of 1 meter, 2 meters . . . L meters (10 meters), the parameter a of the accompanying borehole is collected once, and the stress value b of the corresponding stress gauges 3 in the first accompanying borehole 21, the second accompanying borehole 22, the third accompanying borehole 23 . . . the i-th accompanying borehole 2ᵢ is collected at the same time.

### S3.3: Predictive Modeling Corrections

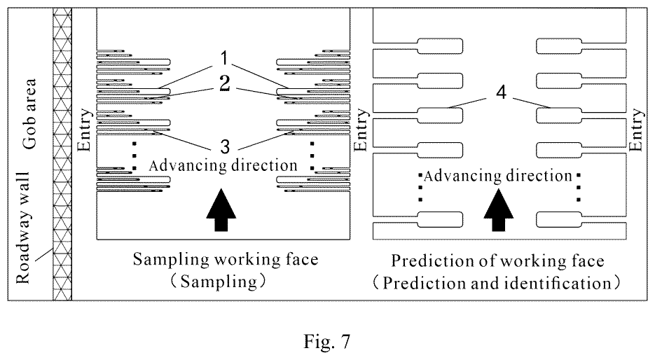

In the correction of the neural network prediction model, a number of stress-monitoring accompanying boreholes of the pressure-relief borehole 1 are also drilled at intervals called validation accompanying boreholes 5 in accordance with the method of Example 1, and the method of drilling the validation accompanying boreholes 5 is carried out in accordance with the method of designing and constructing the neural network prediction model of Step S1. The different diameters accurate pressure relief prediction scheme implemented in the neighboring working face of the sampling working face in accordance with the prediction method of the present invention in Example 2 is shown in FIG. 7.

The present invention has the beneficial effect of also including: (1) based on the intelligent prediction of coal stress change by following drilling parameters, combined with the existing pressure unloading theory, dynamic adjustment and optimization of pressure unloading drilling parameters such as drilling hole diameter and depth are carried out according to the needs of pressure unloading to realize the purpose of accurate pressure unloading; (2) accurately perceive the degree of coal stress concentration, prejudge the degree of impact disaster danger, and provide support for disaster prevention and control; (3) mapping the coal stress distribution law, to provide support for the working face roadway deployment, so that mining working face roadway deployment in avoiding the stress peak location.

It is to be noted that the innovation of the present invention mainly lies in setting up an accompanying borehole at the sampling working face utilizing each pressure-relief borehole. The pressure-relief borehole is used to obtain the stress at different depths of each pressure-relief borehole, and at the same time, the drilling parameters of the pressure-relief borehole are collected, and the one-to-one correspondence between the drilling parameters and the stress value is used for training through a neural network, so as to obtain the optimal neural network prediction model of coal stress. With this model, there is no need to drill a large number of stress monitoring holes in the future face, and only need to calibrate the model every once in a while, so that the stress values at different depths of each pressure-relief borehole can be collected quickly and accurately in real time, so as to obtain the parameters of the different diameters relief boreholes quickly and accurately. As to how to use the neural network to train on the drilling parameters is not the focus of the present invention, such as how to examine the impact of the number of training samples, implied layers, implied layer nodes, and different combinations of input feature parameters on the recognition accuracy of the model, as well as how to set up different numbers of training samples, implied layers, implied layer nodes, and different input feature parameters are all well known in the field of the technology, and the present invention does not make too much statement on this. In addition, the number and depth of accompanying boreholes 2 are determined in the embodiment on the basis of collecting the stress value and the accompanying drilling parameter at one meter per drilling, which is only a scale selected to facilitate operation and data processing under the conditions of considering the cost and the accuracy of the prediction results, and does not serve as a limitation on the technical solution of the present invention. In practice, as long as it can ensure that the acquisition of the accompanying drilling parameters and the stress values are at the same depth, any one of the scales is within the scope of protection of the present invention, and therefore a number of improvements made without departing from the principles described herein should also be regarded as within the scope of protection of the present invention.

What is claimed is:

1. A method of intelligent prediction of coal stress and different diameters pressure relief based on optimization neural network, comprising a computer readable medium operable on a computer with memory for the method of intelligent prediction of coal stress and different diameters pressure relief based on optimization neural network, and comprising program instructions for executing the following steps:
S1: training set data acquisition; wherein the training set data acquisition comprises the steps:
S1.1: selection of a sampling working face in the direction of advance of a mining working face; design of pressure-relief borehole according to underground pressure, and design at least one accompanying borehole for stress monitoring in the vicinity of the pressure-relief borehole;
S1.2: drilling construction and data acquisition; wherein the drilling construction and data acquisition comprises the steps:
S1.2.1: first, the accompanying borehole is drilled, and a method of drilling an accompanying borehole is divided into the following two construction scenarios:
in the first case, when the coal has a Proctor's coefficient value ≥3.0, Proctor's coefficient value is calculated by the formula f=R/10, wherein R is the uniaxial compressive strength of the rock in MPa; the accompanying borehole is near to the pressure-relief borehole and drilled parallel to the pressure-relief borehole; the accompanying borehole and the pressure-relief boreholes are at the same level and at the same depth, and a plurality of borehole stress gauges are set up at equal intervals along the depth in the accompanying borehole;
in the second case, when the coal has a Proctor's coefficient value <3.0, a number of accompanying boreholes with equal depths are drilled around the pressure-relief borehole at equal intervals; the depth of the deepest accompanying borehole is equal to the depth of the pressure-relief borehole, and a borehole stress gauge is placed at the bottom of each accompanying borehole;
S1.2.2: after the accompanying borehole is drilled, drilling of the pressure-relief borehole is started; the pressure-relief borehole is drilled to a position at the same depth as the accompanying borehole's drilled stress gauge, the driller's accompanying drilling parameters are collected as α, and the stress value of that stress gauge is also collected as β;
S2: building a prediction model comprising the following steps:
S2.1: sampling dataset organization comprising the following steps:
the pressure-relief borehole α and the stress value β from the accompanying borehole stress gauges are collected to form a training set during drilling the pressure-relief borehole;
S2.2: establishment of neural network prediction model; wherein the establishment of neural network prediction model comprises the steps:
coefficient of determination R2 is adopted as evaluation index of model prediction accuracy, and different numbers of training samples, hidden layers, hidden layer nodes, and different combinations of drill-following parameters are set as independent variables; the model prediction accuracy is used as the dependent variable to establish a comparative experiment of corresponding artificial neural network model to establish a neural network prediction model;
S2.3: establishment of optimized neural network model; wherein the establishment of optimized neural network model comprises the steps:
genetic algorithm and particle swarm algorithm are used to optimize the neural network prediction model established in S2.2;
S2.4: an optimal neural network prediction model is by comparing the coefficients of determination of a total of three neural network prediction models obtained in steps S2.2 and S2.3;
S3: intelligent prediction of coal stress and different diameters pressure relief; wherein the intelligent prediction of coal stress and different diameters pressure relief comprises the steps:
S3.1: intelligent prediction of coal stresses; wherein the intelligent prediction of coal stresses comprises the steps:
the working face adjacent to the sampling working face was selected as a prediction working face, and the parameters of the accompanying drilling are collected at the same time when the pressure-relief borehole construction was carried out at the prediction working face; the optimal neural network prediction model that has been constructed in step S2 is used to predict the coal stress;
S3.2: determining different diameters pressure relief scheme according to a coal stress distribution comprising the following steps:
based on a predicted value of coal stress, analyze the coal stress distribution law, accordingly determine the different diameters pressure relief scheme;
S3.3: predictive modeling corrections comprising the steps:
the optimal neural network prediction model is corrected at intervals when pressure relief drilling is carried out when predicting the working face; the modified neural network prediction model is utilized to predict the value of the coal stress, and the specific process of the prediction model modification is: when pressure-relief boreholes are drilled in the predicted working face, a number of pressure-relief boreholes are selected at intervals to be drilled for stress monitoring accompanying boreholes as validation accompanying boreholes; construct the validation accompanying borehole in accordance with the method of step S1.2 and collect the stress value β and the accompanying drilling parameter of the pressure-relief borehole α at the corresponding location to form a validation dataset, based on which the optimal neural network prediction model of step S2.4 is validated for error; if the error exceeds a set range, this validation dataset is added to the training set of step S2.1, which in turn corrects the model; the corrected neural network prediction model is used to predict the coal stress values during mining, and if the error is within the set range, the model does not need to be corrected;
S4: regulating pressure for improving construction efficiency and ensuring safe mining based on results of the method of intelligent prediction of coal stress and different diameters pressure relief based on optimization neural network during coal mining.

2. The method for intelligent prediction of coal stress and different diameters pressure relief based on optimization neural network as claimed in claim 1, wherein the driller's accompanying drilling parameters a described in step S1.2.2 comprises a drilling parameter and a vibration parameter; said drilling parameters include rotational speed, feed pressure, motor torque, current voltage and real time power of the motor; said vibration parameters include mean, standard deviation, mean square deviation and center of gravity frequency.

3. The method for intelligent prediction of coal stress and different diameters pressure relief based on optimization neural network as claimed in claim 1, wherein the step 3.2 further comprises: determining the location of the reaming and the length of the borehole section of the unloading borehole based on the distribution of the high stress zone; determine the hole diameter of reaming according to the size of the stress in the high stress zone, and when the pressure-relief borehole is drilled to the reaming position, implement the reaming construction according to the determined reaming section length and hole diameter size.
